(19) United States
(12) Patent Application Publication
(10) Pub. No.: US 2024/0178329 A1
(43) Pub. Date: May 30, 2024

(54) SEMICONDUCTOR PACKAGES WITH SIDE-FACING AMBIENT LIGHT SENSORS

(71) Applicant: TEXAS INSTRUMENTS INCORPORATED, Dallas, TX (US)

(72) Inventor: Masamitsu MATSUURA, Beppu-Shi (JP)

(21) Appl. No.: 18/072,456

(22) Filed: Nov. 30, 2022

(51) Int. Cl. H01L 31/0203; H01L 31/02; H01L 31/18

(52) U.S. Cl. CPC H01L 31/0203; H01L 31/02002; H01L 31/18

(57) ABSTRACT

In examples, a semiconductor package comprises a semiconductor die including an ambient light sensor, the ambient light sensor facing a horizontal direction. The package includes first and second conductive terminals wirebonded to the semiconductor die, each of the first and second conductive terminals having first and second segments. The package includes a clear mold compound covering the semiconductor die and portions of the first and second conductive terminals. The first segments of the first and second conductive terminals extend vertically through the clear mold compound to an exterior of the clear mold compound, and wherein the second segments of the first and second conductive terminals are positioned exterior to the clear mold compound, extend horizontally in opposing directions, and are adapted to be coupled to a printed circuit board.

### BACKGROUND

Some semiconductor packages are configured to sense light. These light-sensing semiconductor packages may include clear mold compounds and semiconductor dies that include ambient light sensors. Ambient light passes through the clear mold compound of the semiconductor package and is captured by the ambient light sensor of the semiconductor die within the package. Circuitry in the semiconductor die may then process and analyze signals representing the captured light.

### SUMMARY

In examples, a semiconductor package comprises a semiconductor die including an ambient light sensor, the ambient light sensor facing a horizontal direction. The package includes first and second conductive terminals wirebonded to the semiconductor die, each of the first and second conductive terminals having first and second segments. The package includes a clear mold compound covering the semiconductor die and portions of the first and second conductive terminals. The first segments of the first and second conductive terminals extend vertically through the clear mold compound to an exterior of the clear mold compound, and wherein the second segments of the first and second conductive terminals are positioned exterior to the clear mold compound, extend horizontally in opposing directions, and are adapted to be coupled to a printed circuit board.

In examples, a method for manufacturing a semiconductor die comprises providing a lead frame having a die pad and an array of conductive terminals, each of the conductive terminals in the array of conductive terminals having first and second segments. The method also includes coupling a semiconductor die to the die pad and to the array of conductive terminals, the semiconductor die having an ambient light sensor facing a first direction. The method also includes covering the semiconductor die and portions of the first segments of the conductive terminals in the array of conductive terminals with a clear mold compound. The method includes bending the second segments of a first set of conductive terminals in the array of conductive terminals in a second direction. The method also comprises bending the second segments of a second set of conductive terminals in the array of conductive terminals in the first direction, the conductive terminals bent in the first direction interleaved with the conductive terminals bent in the second direction.

### BRIEF DESCRIPTION OF THE DRAWINGS

FIGS. 1A-1E are perspective, top-down, rear, profile, and frontal views, respectively, of a semiconductor package with a side-facing ambient light sensor, in accordance with various examples.

FIGS. 2A-2G are perspective views of a manufacturing process flow for a semiconductor package with a side-facing ambient light sensor, in accordance with various examples.

FIG. 3 is a flow diagram of a method for manufacturing a semiconductor package with a side-facing ambient light sensor, in accordance with various examples.

FIGS. 4A-4J are various views of a semiconductor package with a side-facing ambient light sensor, in accordance with various examples.

FIGS. 5A-5C are profile, top-down, and perspective see-through views, respectively, of an electronic device including a semiconductor package with a side-facing ambient light sensor, in accordance with various examples.

FIGS. 6A and 6B are profile and cross-sectional external views, respectively, of an electronic device including a semiconductor package with a side-facing ambient light sensor, in accordance with various examples.

### DETAILED DESCRIPTION

Electronic devices used in light-sensing applications may include light-sensing semiconductor packages. More specifically, an electronic device may include a printed circuit board (PCB) on which a light-sensing semiconductor package is mounted. The electronic device may have a wall or surface including a window through which light can pass and reach the light-sensing semiconductor package on the PCB. Because of the way PCBs are oriented relative to electronic device windows, a light-sensing semiconductor package is able to capture light from a window that is located directly above the semiconductor package, but the package is unable to capture light from a window that is located lateral to (to the side of) the semiconductor package.

This disclosure describes various examples of light-sensing semiconductor packages configured to capture light from electronic device windows located lateral to the semiconductor packages. For example, an electronic device may include a surface or wall having a window and may further include a PCB that is oriented perpendicular to the window. Prior light-sensing semiconductor packages mounted to the PCB would not be able to capture light from such a window, but the light-sensing semiconductor packages described herein are able to capture light from such windows. Accordingly, such light-sensing semiconductor packages expand the range of electronic devices that can provide light-sensing capabilities.

In examples, a semiconductor package comprises a semiconductor die including an ambient light sensor. The ambient light sensor faces a horizontal direction. The package also includes first and second conductive terminals wirebonded to the semiconductor die. Each of the first and second conductive terminals has first and second segments. The package also comprises a clear mold compound covering the semiconductor die and portions of the first and second conductive terminals. The first segments of the first and second conductive terminals extend vertically through the clear mold compound to an exterior of the clear mold compound. The second segments of the first and second conductive terminals are positioned exterior to the clear mold compound, extend horizontally in opposing directions, and are adapted to be coupled to a printed circuit board.

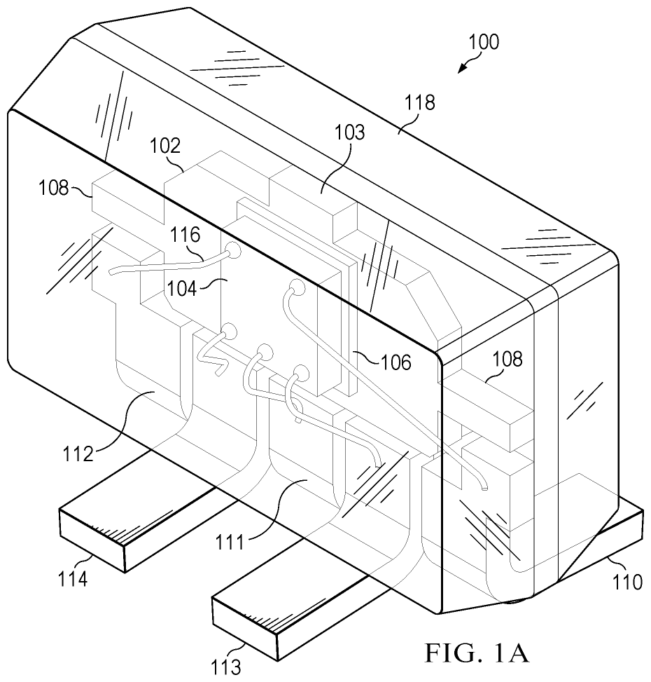

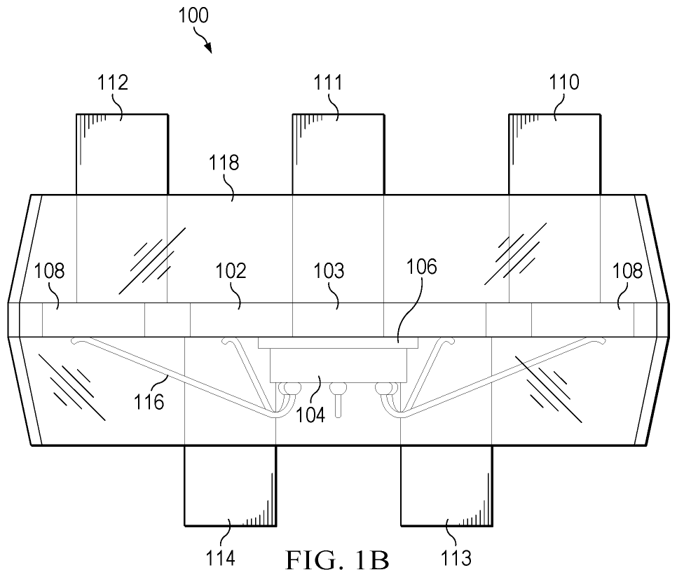

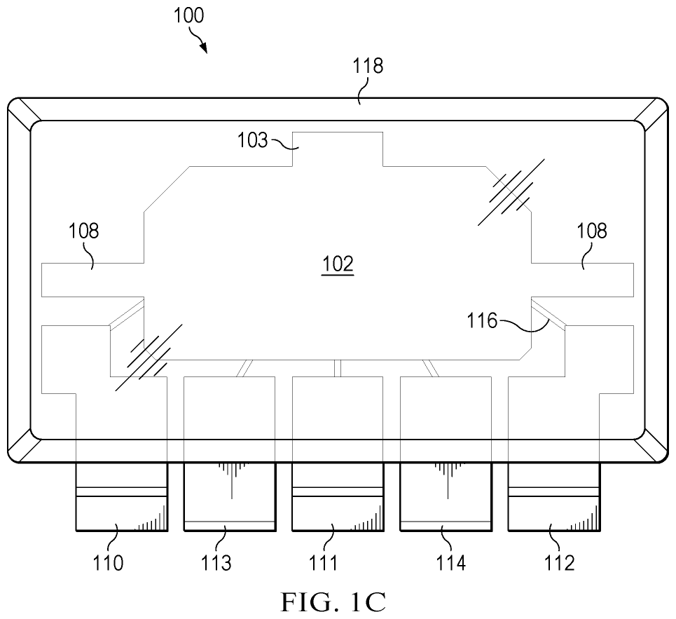

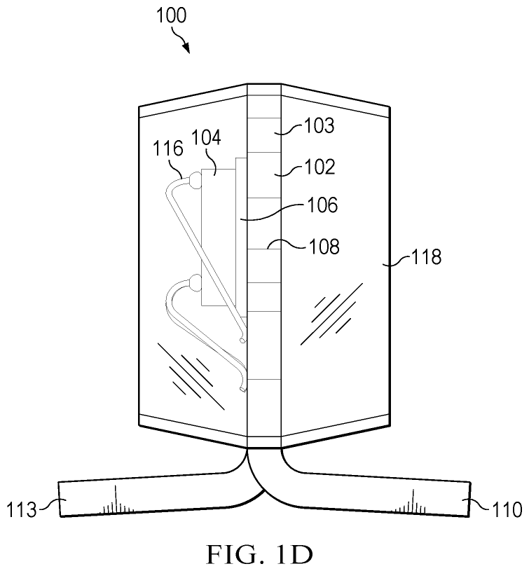

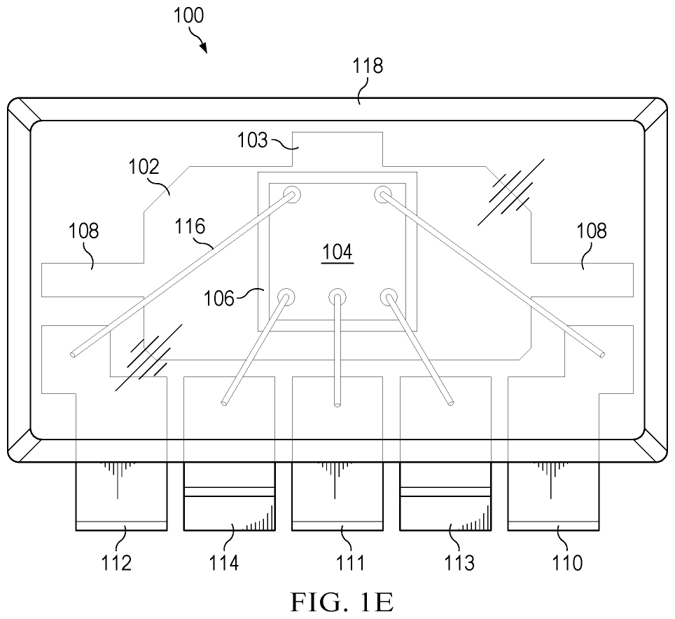

FIG. 1A is a perspective view of a semiconductor package 100 with a side-facing ambient light sensor, in accordance with various examples. More specifically, the semiconductor package 100 includes a die pad 102, support bar stubs 103 extending from the die pad 102, and a semiconductor die 104 coupled to the die pad 102 by way of a die attach layer 106. The semiconductor package 100 also includes support bar stubs 108 extending from the die pad 102. In examples, the semiconductor package 100 is a surface mount type package, and as such, the semiconductor package 100 includes conductive terminals 110-114 that are coupled (e.g., wirebonded) to the semiconductor die 104 by way of bond wires 116. A transparent or translucent mold compound 118 covers some or all of the various components of the semiconductor package 100.

In examples, the semiconductor die 104 includes an ambient light sensor to capture ambient light. In examples, the ambient light sensor of the semiconductor die 104 is oriented vertically and faces in a horizontal direction away from the die pad 102. In this description, the term “horizontal” refers to a direction that is approximately perpendicular with the orientation of the die pad 102. Conversely, the term “vertical” refers to a direction that is approximately parallel with the orientation of the die pad 102. The semiconductor die 104 may include circuitry coupled to the ambient light sensor. Such circuitry may process electrical signals representative of the captured light in any suitable manner. The semiconductor die 104 may include bond pads and/or appropriate conductive structures that establish electrical pathways between the bond pads and/or the circuitry described above. In this way, the semiconductor die 104 captures ambient light by the ambient light sensor, processes electrical signals representative of the captured light using the circuitry, and provides signals produced as a result of such processing to other components (e.g., components co-located on a printed circuit board with the semiconductor package 100) via the bond pads, the bond wires 116 that are coupled to such bond pads, and the conductive terminals 110-114.

In examples, each of the conductive terminals 110-114 includes a first segment and a second segment. The first segment of each conductive terminal 110-114 couples to a different bond wire 116, extends vertically and downward away from the semiconductor die 104, extends through one or more surfaces of the mold compound 118 (e.g., extends through a single surface of the mold compound 118; extends through a seam at which multiple surfaces of the mold compound 118 meet), and extends vertically and downward away from the mold compound 118, as FIG. 1A shows. The second segment of each conductive terminal 110-114 extends horizontally. In examples, the second segments of the conductive terminals 110-114 all extend in the same horizontal direction. In examples, the second segments of the conductive terminals 110-114 extend in multiple horizontal directions. In examples, the second segments of the conductive terminals 110-114 extend in multiple horizontal directions in an interleaved fashion, as FIG. 1A shows. For instance, FIG. 1A shows the second segments of the conductive terminals 110-112 extending in a first horizontal direction and the second segments of the conductive terminals 113 and 114 extending in a second horizontal direction that is opposite the first horizontal direction. Each of the conductive terminals 110-114 may be a monolithic metal member that has been bent during manufacture to produce first and second segments that extend in different directions.

In examples, the first segments of the conductive terminals 110-114 are contained entirely within the mold compound 118. In examples, the first segments of the conductive terminals 110-114 are partially contained within the mold compound 118 and are partially outside the mold compound 118. In examples, the second segments of the conductive terminals 110-114 are at least partially contained within the mold compound 118. For example, the bottom surfaces of the second segments could be flush with the bottom surface of the mold compound 118. In such examples, the bottom surface of the mold compound 118 may be flat. In some examples, the second segments of the conductive terminals 110-114 are located entirely outside of the mold compound 118. FIGS. 1B-1E are top-down, rear, profile, and frontal views, respectively, of the semiconductor package 100, in accordance with various examples.

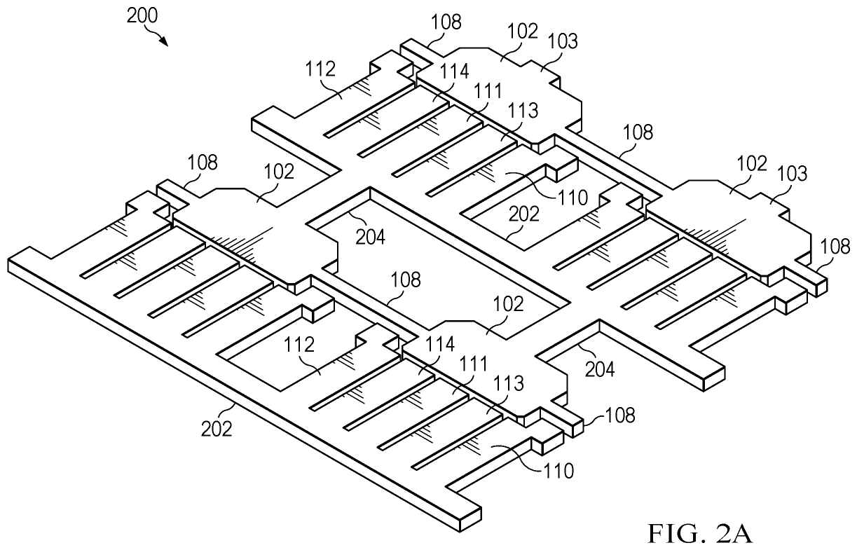

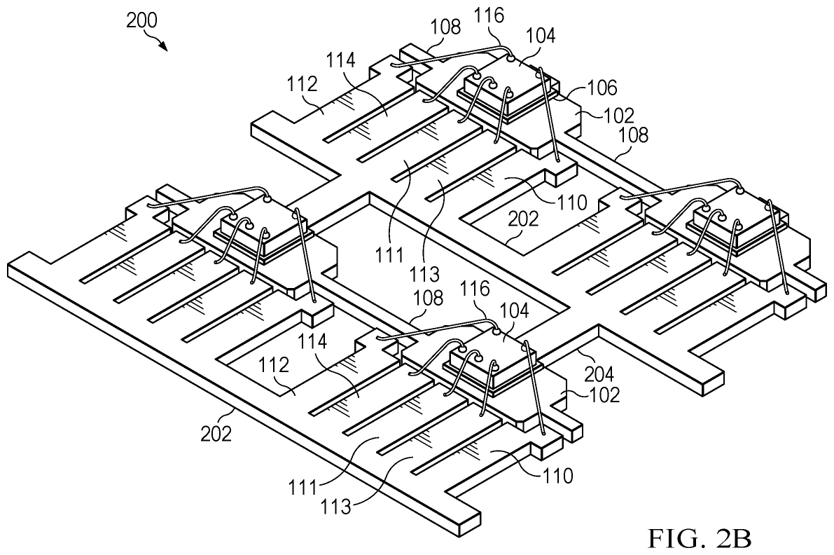

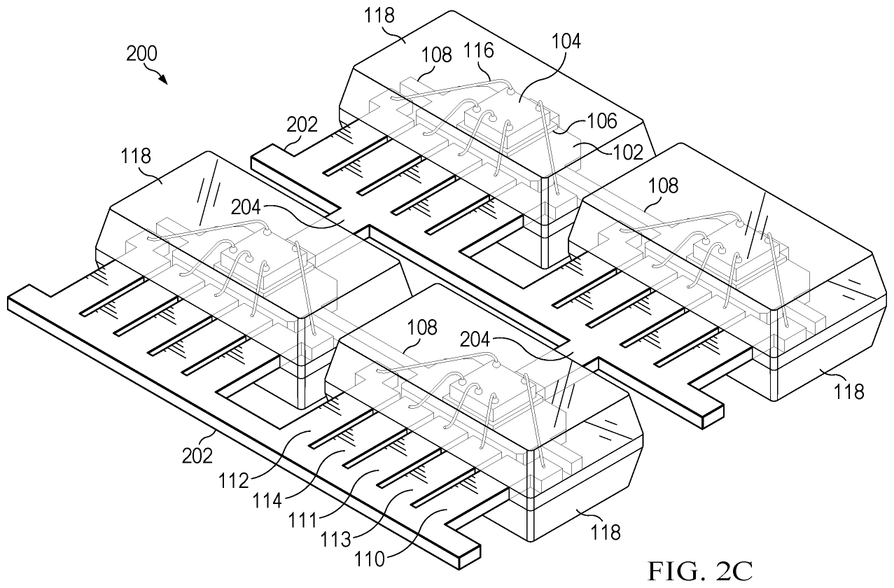

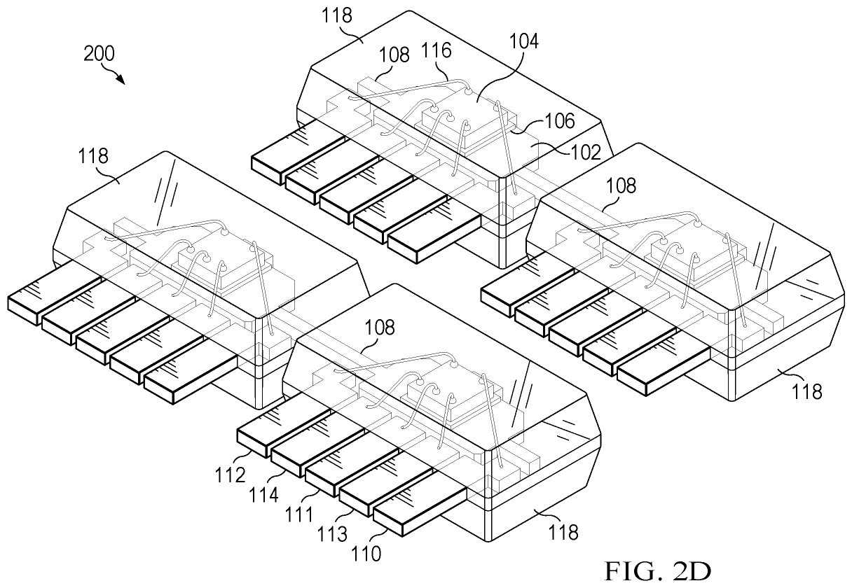

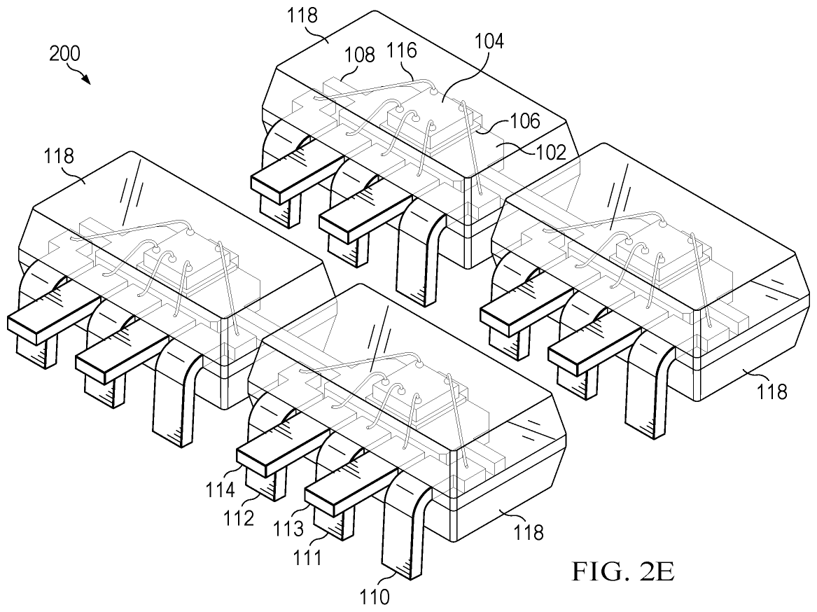

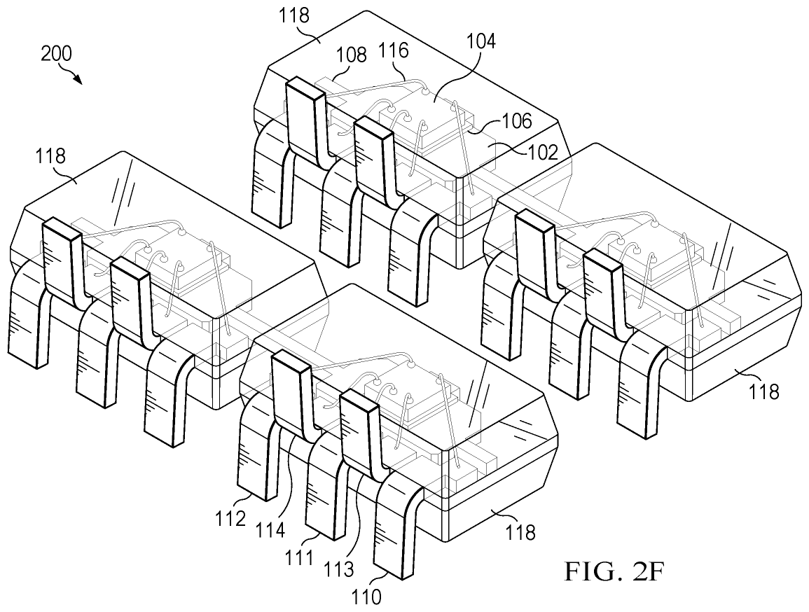

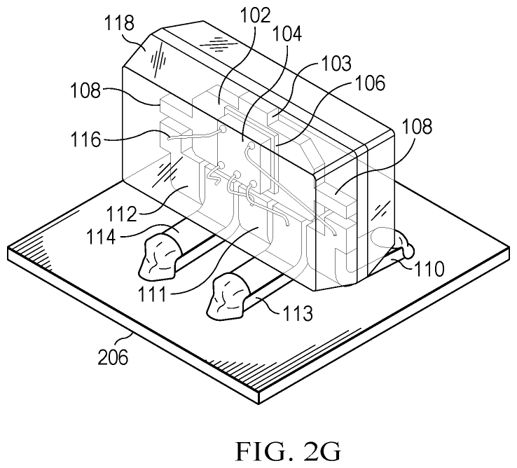

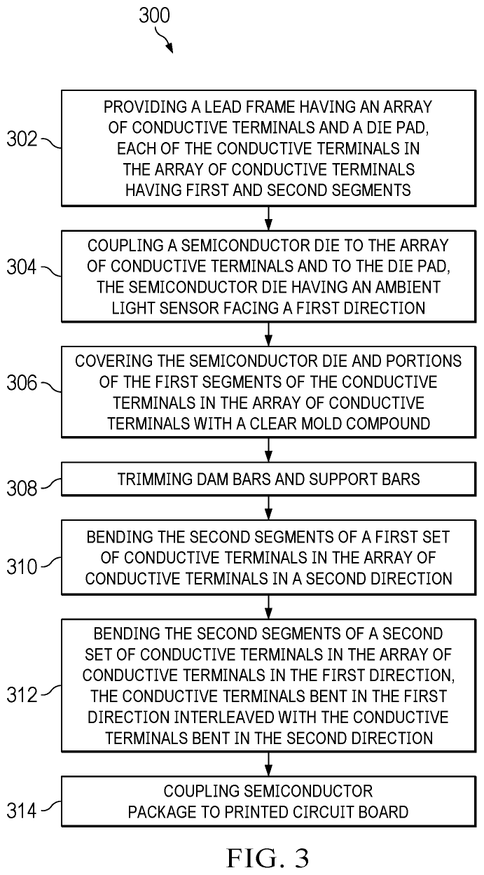

FIGS. 2A-2G are perspective views of a manufacturing process flow for the semiconductor package 100, in accordance with various examples. FIG. 3 is a flow diagram of a method 300 for manufacturing the semiconductor package 100, in accordance with various examples. The method 300 begins with providing a lead frame having an array of conductive terminals and a die pad, with each of the conductive terminals in the array of conductive terminals having first and second segments (302). FIG. 2A shows a lead frame 200 having multiple die pads 102, multiple sets of conductive terminals 110-114, multiple dam bars 202, and multiple support bars 204. Each of the conductive terminals 110-114 includes first and second segments. Each dam bar 202 couples multiple conductive terminals 110-114 together. Each support bar 204 couples a die pad 102 to a dam bar 202. In examples, the lead frame 200 comprises copper, but other metals or alloys also may be useful.

The method 300 includes coupling a semiconductor die to the array of conductive terminals and to the die pad, the semiconductor die having an ambient light sensor facing a first direction (304). FIG. 2B shows the structure of FIG. 2A, with the addition of semiconductor dies 104 coupled to respective die pads 102 by way of die attach layers 106. The semiconductor dies 104 include ambient light sensors, as described above. Each of the semiconductor dies 104 may also include bond pads on a surface of the semiconductor die 104 through which light is captured by the ambient light sensor (also referred to herein as the device side of the semiconductor die 104). Bond wires 116 are coupled between the conductive terminals 110-114 (e.g., the first segments of the conductive terminals 110-114) and the bond pads of the semiconductor die 104. Any suitable wire bonding technique, such as a stitch bond technique, may be used. In examples, the surfaces of the semiconductor dies 104 to which the bond pads are coupled and through which ambient light is captured by ambient light sensors face away from the die pads 102.

The method 300 includes covering the semiconductor die and portions of the first segments of the conductive terminals in the array of conductive terminals with a clear mold compound (306). FIG. 2C shows the semiconductor dies 104, bond wires 116, die pads 102, and portions of the conductive terminals 110-114 being covered by a clear mold compound 118. In examples, the clear mold compound 118 covers only a portion of each conductive terminal 110-114 (e.g., a portion of the first segment of each conductive terminal 110-114, the first segment of each conductive terminal 110-114 being more proximal to the respective die pad 102 than a second segment of each conductive terminal 110-114). In examples, the clear mold compound 118 is applied by transfer molding using a mold chase that includes separate chambers for each die pad 102. In other examples, the clear mold compound 118 covers multiple die pads 102 (as well as the respective semiconductor dies 104, bond wires 116, and conductive terminals 110-114), and the clear mold compound 118 is later singulated (e.g., trimmed by a punching tool) to produce multiple, individual, clear mold compounds 118, each covering a different semiconductor die 104, set of bond wires 116, die pad 102, and set of conductive terminals 110-114. The clear mold compound 118 may have any suitable shape. In the example of FIG. 2C, the clear mold compound 118 has a hexagonal shape along a short-axis cross-section, and a rectangular shape along a long-axis cross-section. In examples, the clear mold compound 118 is transparent. In examples, the clear mold compound 118 is translucent, and in such examples, the clear mold compound 118 has a translucency (e.g., light permittivity) range of 99.9% to 60%. A less translucent clear mold compound is disadvantageous because inadequate light is captured by the ambient light sensor for most or all translucent applications.

The method 300 includes trimming the dam bars and support bars (308). FIG. 2D shows the dam bars 202 and support bars 204 having been trimmed.

The method 300 includes bending the second segments of a first set of conductive terminals in the array of conductive terminals in a second direction (310). FIG. 2E shows the second segments (e.g., the second segment of each conductive terminal 110-114 being more distal to the die pad 102 than the first segment of each respective conductive terminal 110-114) of conductive terminals 110-112 being bent in the second direction. The first and second directions are horizontally opposing directions. In step 310, the conductive terminals 110-112 corresponding to each of the die pads 102 may be bent, as FIG. 2E shows.

The method 300 includes bending the second segments of a second set of conductive terminals in the array of conductive terminals in the first direction (312). In some examples, the conductive terminals bent in the first direction may be interleaved with the conductive terminals bent in the second direction (312). FIG. 2F shows the second segments of the conductive terminals 113 and 114 being bent in the first direction, which is the same direction as that which the ambient light sensor of the semiconductor die 104 faces. In step 312, the conductive terminals 113 and 114 corresponding to each of the die pads 102 may be bent, as FIG. 2F shows. The bar stubs 108 may be formed by trimming the bars at any suitable time in the process.

The method 300 includes coupling the semiconductor package to a printed circuit board (PCB) (314). FIG. 2G shows an example semiconductor package 100 that has been formed by the method 300 being coupled to a PCB 206. In examples, the second segments of the conductive terminals 110-114 are soldered to the PCB 206, such as to metal traces or pads (not expressly shown) on the PCB 206.

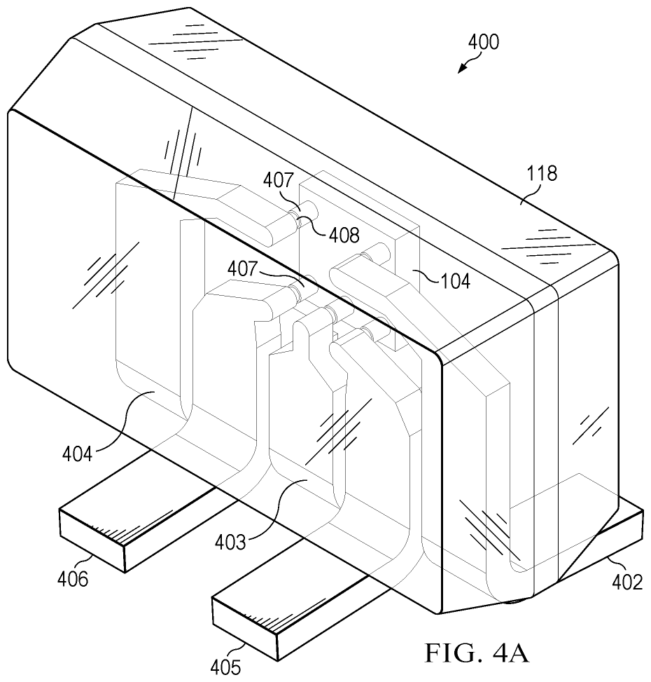

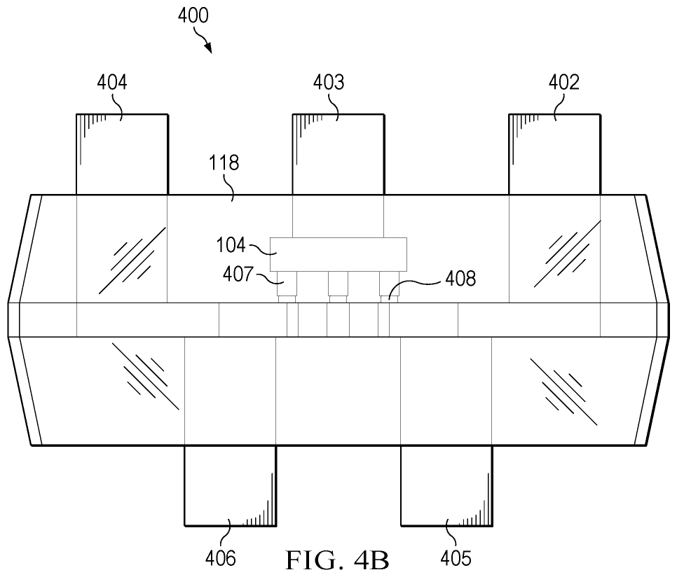

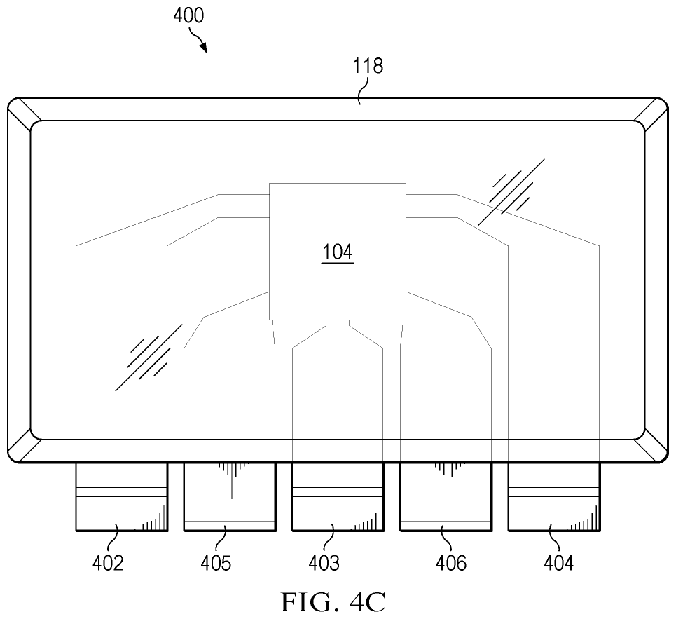

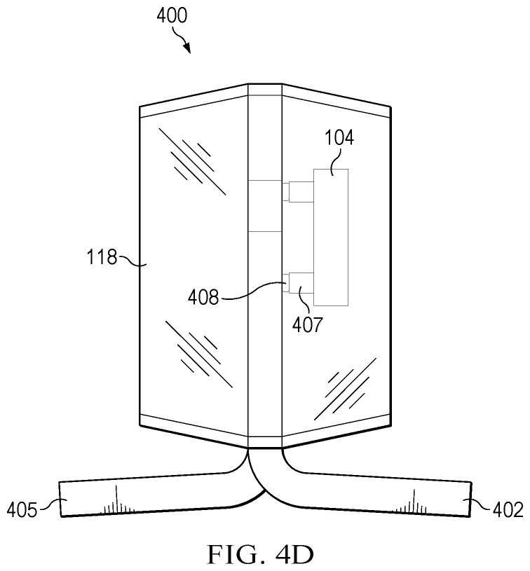

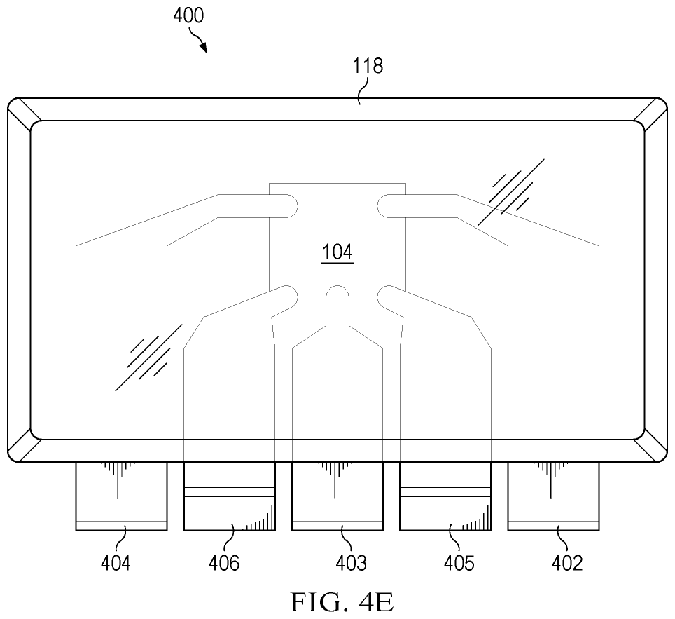

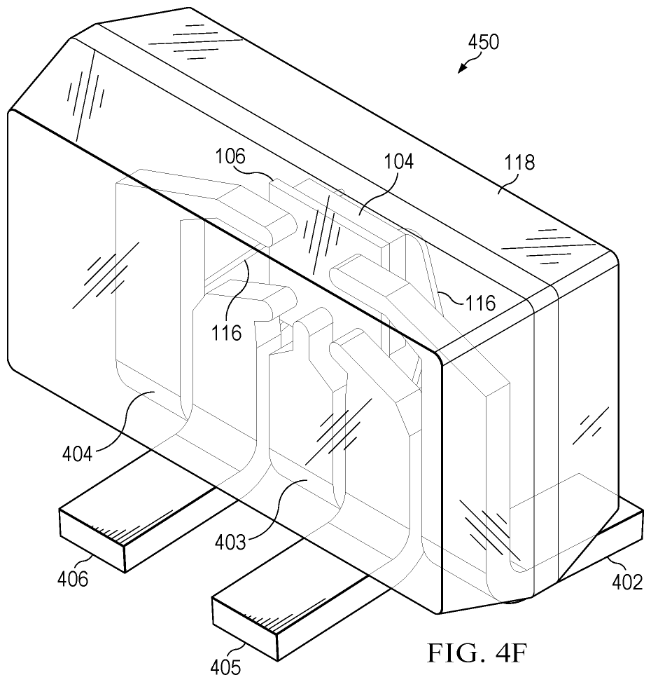

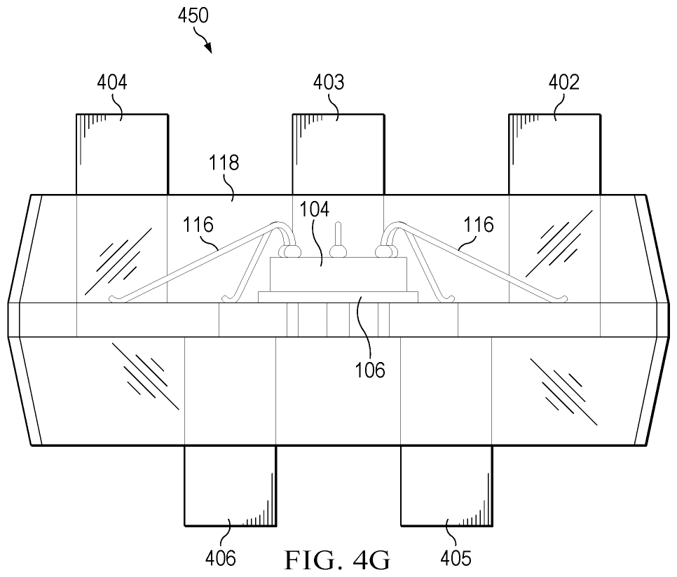

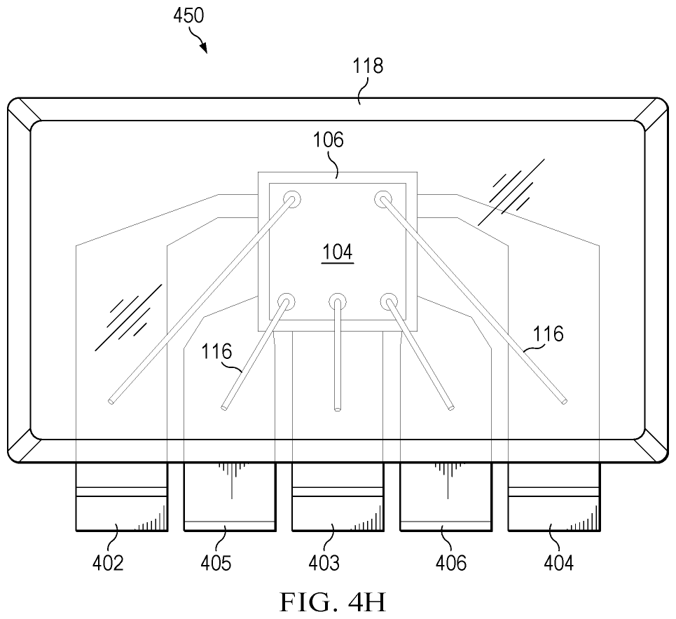

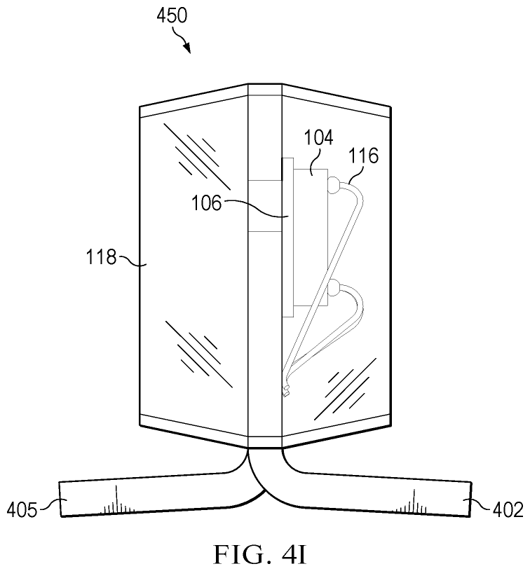

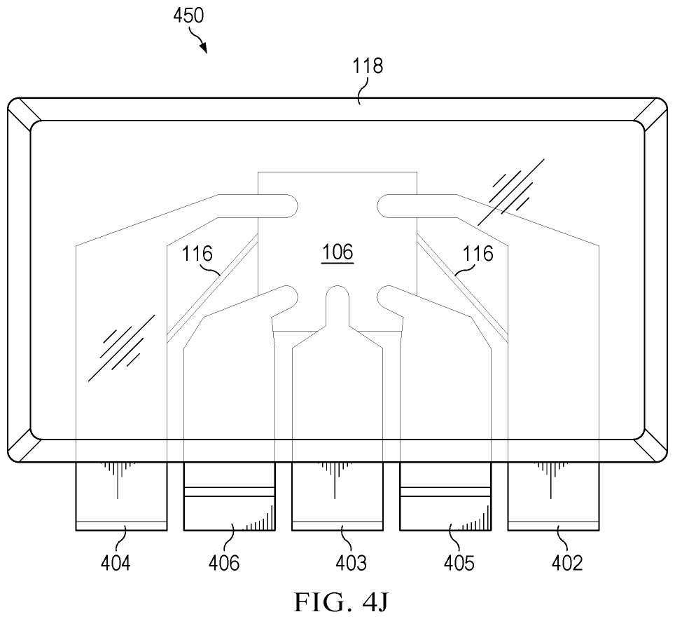

Although FIGS. 1A-1E and 2A-2G describe semiconductor packages 100 having wire bond connections between the semiconductor dies 104 and conductive terminals 110-114, the scope of this disclosure is not limited as such. In examples, solder members may be useful to couple the semiconductor dies 104 to conductive terminals 110-114 and may be used in lieu of bond wires. FIGS. 4A-4E are perspective, top-down, rear, profile, and frontal views, respectively, of a semiconductor package 400 with a side-facing ambient light sensor, in accordance with various examples. The semiconductor package 400 includes a semiconductor die 104. The semiconductor die 104 is described above, and thus is not described again in detail here. Conductive pathways of the semiconductor die 104 are coupled to conductive terminals 402-406 by way of copper pillars 407 and solder members 408 that are between the copper pillars 407 and respective conductive terminals 402-406. In some examples, the copper pillars 407 are formed on the semiconductor die 104 and are coupled to the conductive terminals 402-406 by way of solder members 408, and in other examples, the copper pillars 407 are formed on the conductive terminals 402-406 and are coupled to the semiconductor die 104 by way of solder members 408. In examples, the semiconductor package 400 is a surface mount type package. The conductive terminals 402-406 have first and second segments. The first segments of the conductive terminals 402-406 are more proximal to the semiconductor die 104 than the second segments of the conductive terminals 402-406. The first segments of the conductive terminals 402-406 are coupled to the semiconductor die 104 by way of solder members 408 and copper pillars 407 and extend away from the semiconductor die 104 and through one or more surfaces of the mold compound 118. (In some examples, copper pillars 407 are omitted and the connections are established solely with solder members 408.) In examples, the mold compound 118 covers part of each first segment of the conductive terminals 402-406, and in other examples, the mold compound 118 covers all of each first segment of the conductive terminals 402-406. The second segments of the conductive terminals 402-406 extend horizontally, as shown. In examples, the second segments of the conductive terminals 402-406 extend in multiple horizontal directions, with some extending in a first horizontal direction and others extending in a second horizontal direction. In examples, the second segments of the conductive terminals 405 and 406 extend in a first horizontal direction (e.g., the direction in which the ambient light sensor of the semiconductor die 104 faces), and the second segments of the conductive terminals 402-404 extend in a second horizontal direction (e.g., the direction opposite the first direction), such that the differing directions in which the second segments extend are arranged in an interleaving configuration. Other configurations are contemplated and included in the scope of this disclosure.

FIGS. 4F-4J are perspective, top-down, frontal, profile, and rear views of a semiconductor package 450, in accordance with various examples. The semiconductor package 450 omits a die pad. Instead, conductive terminals 402-406 are coupled to the semiconductor die 104 by way of a die attach layer (e.g., die attach film) 106. A device side (e.g., photosensitive side having an ambient light sensor) of the semiconductor die 104 faces away from the die attach layer 106. Bond wires 116 couple the device side of the semiconductor die 104 (e.g., bond pads on the device side of the semiconductor die 104) to the conductive terminals 402-406. The remainder of the semiconductor package 450 is similar in structure and operation to the semiconductor package 400 described above.

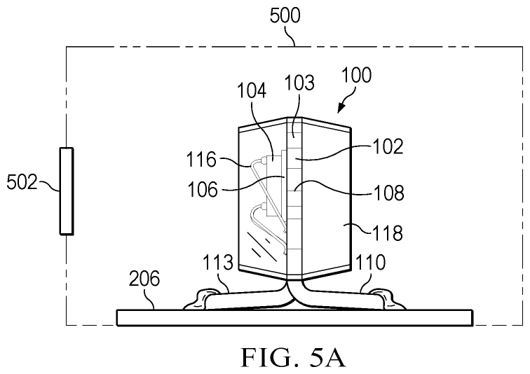

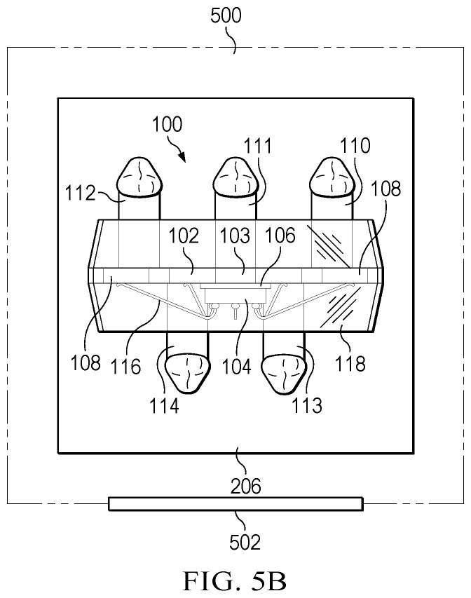

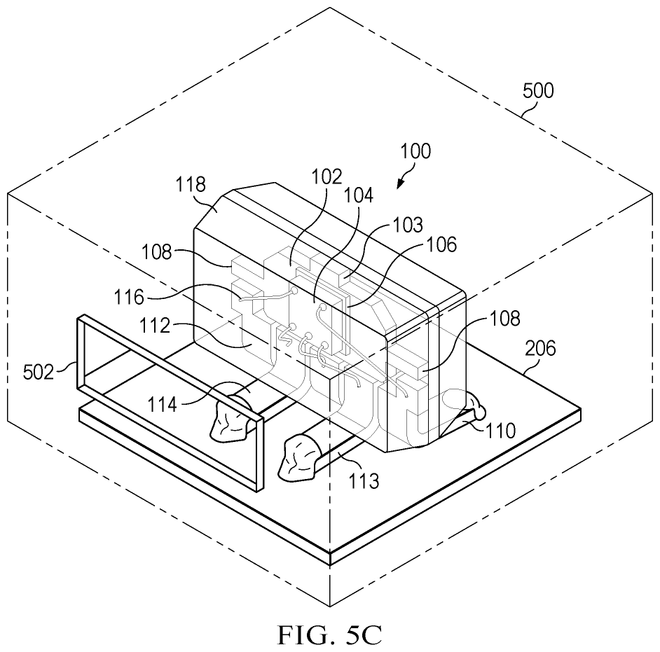

FIGS. 5A-5C are profile, top-down, and perspective see-through views, respectively, of an electronic device including a semiconductor package with a side-facing ambient light sensor, in accordance with various examples. In examples, the electronic device 500 is a light sensing device, such as may be useful in a laptop computer, a smartphone, a desktop computer, a tablet, a notebook, a television, a lighting application, an appliance, an automobile, an aircraft, a spacecraft, etc. The electronic device 500 includes a window 502 through which ambient light may enter the electronic device 500. The example electronic device 500 includes a semiconductor package 100, such as that described herein. Light entering the window 502 extends toward and enters the clear mold compound 118 of the semiconductor package 100 and is captured by the ambient light sensor of the semiconductor die 104. In examples, the electronic device 500 includes a PCB 206 to which the semiconductor package 100 is coupled. In examples, the PCB 206 is oriented approximately perpendicular to the approximately vertical plane in which the window 502 lies. In examples, the semiconductor package 100 is oriented approximately perpendicular to the approximately horizontal plane in which the PCB 206 lies. In examples, the semiconductor package 400 (FIGS. 4A-4E) or 450 (FIGS. 4F-4J) may replace the semiconductor package 100 in the electronic device 500.

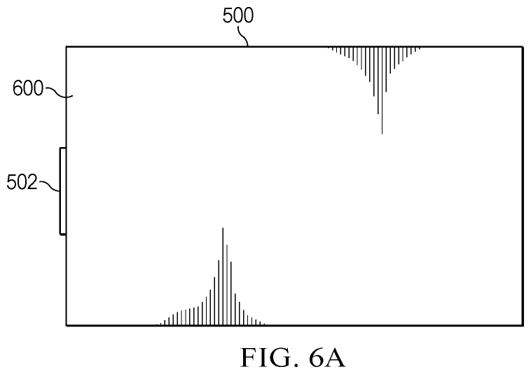

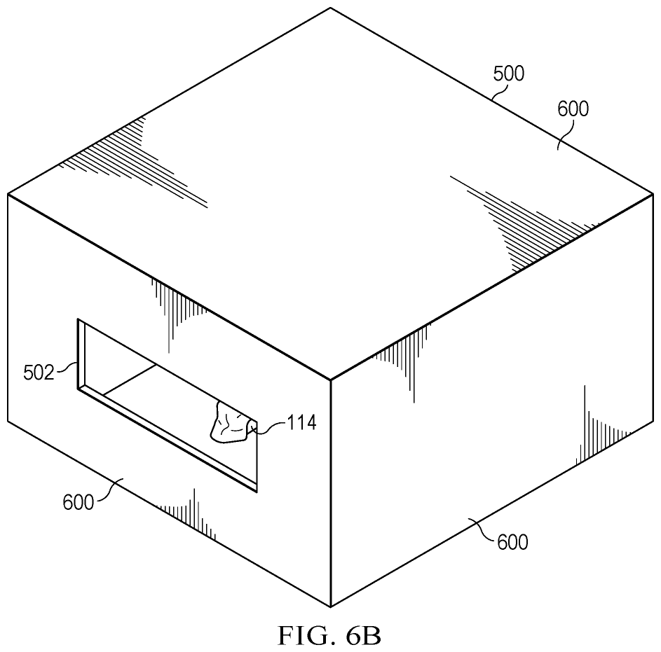

FIGS. 6A and 6B are profile and perspective external views, respectively, of the electronic device 500, in accordance with various examples. The electronic device 500 may include the window 502, as shown, and may further include opaque walls 600, as shown.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die including an ambient light sensor, the ambient light sensor facing a horizontal direction;
first and second conductive terminals wirebonded to the semiconductor die, each of the first and second conductive terminals having first and second segments; and
a clear mold compound covering the semiconductor die and portions of the first and second conductive terminals,
wherein the first segments of the first and second conductive terminals extend vertically through the clear mold compound to an exterior of the clear mold compound, and wherein the second segments of the first and second conductive terminals are positioned exterior to the clear mold compound, extend horizontally in opposing directions, and are adapted to be coupled to a printed circuit board.

2. The semiconductor package of claim 1, further comprising third and fourth conductive terminals coupled to the semiconductor die and having first and second segments, the first segment of the second conductive terminal between the first segments of the first and third conductive terminals, and the first segment of the third conductive terminal between the first segments of the second and fourth conductive terminals, the second segments of the first and third conductive terminals extending in a first horizontal direction, and the second segments of the second and fourth conductive terminals extending in a second horizontal direction.

3. The semiconductor package of claim 2, wherein the first and second horizontal directions oppose each other.

4. The semiconductor package of claim 1, wherein the first and second conductive terminals extend through a same surface of the clear mold compound.

5. The semiconductor package of claim 1, wherein the semiconductor package is a surface mount type package.

6. A semiconductor package, comprising:
a semiconductor die having a device side including an ambient light sensor, the ambient light sensor facing a first direction;
first and second conductive terminals, each of the first and second conductive terminals having first and second segments, the first segments soldered to the device side of the semiconductor die, the first segments extending away from the semiconductor die in a second direction approximately perpendicular to the first direction, the second segments extending in opposing directions, each of the opposing directions approximately perpendicular to the second direction, the second segments adapted to be coupled to a printed circuit board; and
a clear mold compound covering the semiconductor die and portions of the first segments.

7. The semiconductor package of claim 6, further comprising third and fourth conductive terminals coupled to the semiconductor die and having first and second segments, the first segment of the second conductive terminal between the first segments of the first and third conductive terminals, and the first segment of the third conductive terminal between the first segments of the second and fourth conductive terminals, the second segments of the first and third conductive terminals extending in a first horizontal direction, and the second segments of the second and fourth conductive terminals extending in a second horizontal direction.

8. The semiconductor package of claim 7, wherein the first and second horizontal directions oppose each other.

9. The semiconductor package of claim 6, wherein the first and second conductive terminals extend through a same surface of the clear mold compound.

10. The semiconductor package of claim 6, wherein the semiconductor package is a surface mount type package.

11. A method for manufacturing a semiconductor die, comprising:
providing a lead frame having a die pad and an array of conductive terminals, each of the conductive terminals in the array of conductive terminals having first and second segments;
coupling a semiconductor die to the die pad and to the array of conductive terminals, the semiconductor die having an ambient light sensor facing a first direction;
covering the semiconductor die and portions of the first segments of the conductive terminals in the array of conductive terminals with a clear mold compound;
bending the second segments of a first set of conductive terminals in the array of conductive terminals in a second direction; and
bending the second segments of a second set of conductive terminals in the array of conductive terminals in the first direction, the conductive terminals bent in the first direction interleaved with the conductive terminals bent in the second direction.

12. The method of claim 11, wherein the first and second sets of conductive terminals are interleaved in the array of conductive terminals.

13. The method of claim 11, wherein the first and second directions are opposing horizontal directions.

14. The method of claim 11, wherein the first and second sets of conductive terminals extend through a same surface of the clear mold compound.

15. The method of claim 11, wherein the semiconductor die is within a surface mount type semiconductor package.

16. The method of claim 11, wherein coupling the semiconductor die to the array of conductive terminals comprises wirebonding the semiconductor die to the array of conductive terminals.

17. The method of claim 11, wherein coupling the semiconductor die to the array of conductive terminals comprises soldering the semiconductor die to the array of conductive terminals.
